(19) United States
(12) Patent Application Publication
(10) Pub. No.: US 2008/0290380 A1
(43) Pub. Date: Nov. 27, 2008

(54) SEMICONDUCTOR DEVICE WITH RAISED SPACERS

(75) Inventors: Yi-Ming Sheu, Hsinchu (TW); Da-Wen Lin, Taiping City (TW); Shyh-Wei Wang, Hsinchu County (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/753,374

(22) Filed: May 24, 2007

(51) Int. Cl. H01L 29/78; H01L 21/336

(52) U.S. Cl. 257/288; 438/305; 257/E29.266; 257/E21.437

(57) ABSTRACT

A semiconductor device includes a substrate and a gate formed on the substrate. A gate spacer is formed next to the gate. The gate spacer has a height greater than the height of the gate. A method of forming a semiconductor device includes providing a substrate with a gate layer. A hard mask layer is formed over the gate layer, and both layers are then etched using a pattern, forming a gate and a hard mask. A spacer layer is then deposited over the substrate, gate, and hard mask. The spacer layer is etched to form a gate spacer next to the gate. The hard mask is then removed.

### BACKGROUND

Semiconductor devices continue to get smaller as manufacturers find new ways to reduce their size. As features are scaled to smaller dimensions, the physical stresses in different regions of the semiconductor device gain greater significance. The physical stress may be compressive or tensile. By altering the physical stress in a semiconductor device, the mobility of charge carriers (electrons and holes) may be changed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. Furthermore, all features may not be shown in all drawings for simplicity.

FIG. 1 illustrates a cross-sectional view of one embodiment of a semiconductor device.

FIG. 2 illustrates a cross-sectional view of another embodiment of a semiconductor device.

FIGS. 3a-3f illustrate an exemplary series of cross-sectional views showing intermediate steps of one embodiment of a method for fabricating a semiconductor device.

FIG. 4 illustrates an exemplary method for forming a semiconductor device.

FIG. 5 illustrates another exemplary method for forming a semiconductor device.

### DETAILED DESCRIPTION

The present disclosure relates generally to semiconductor manufacturing and a method of forming a semiconductor device. It is understood, however, that the following disclosure provides many different embodiments, or examples, for implementing different features of the invention. Specific examples of components and arrangements are described below to simplify the present disclosure. These descriptions are merely examples and are not intended to be limiting.

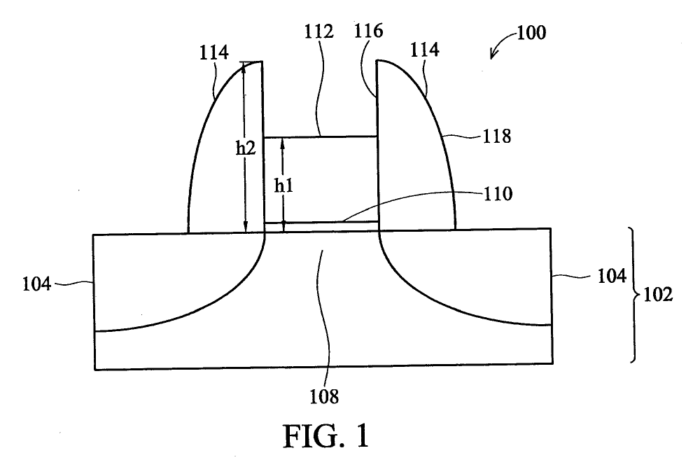

Referring to FIG. 1, illustrated is a cross-sectional view a semiconductor device 100. The device 100 includes a substrate 102, which may include silicon, germanium, silicon-on-insulator (SOI), silicon with defective crystalline, and/or diamond or other suitable materials. The substrate 102 may be n-type doped or p-type doped. The substrate 102 may be provided with one or more isolation features (not shown). The isolation features may include local oxidation of silicon (LOCOS) structures and/or shallow trench isolation (STI) structures that are formed in the substrate 102 to electrically isolate device areas.

The substrate 102 includes a source region 104 and a drain region 106. The source region 104 and the drain region 106 may be n-type doped or p-type doped. In some embodiments, the source region 104 and the drain region 106 are doped similarly to one another and differently than other regions of substrate 102. The substrate 102 also includes a channel region 108 between source region 104 and drain region 106. The channel region 108 may be n-type doped or p-type doped, and in one embodiment it may be doped differently than the source region 104 and the drain region 106.

The device 100 also includes a gate dielectric 110, which may be a layer of a dielectric material. The gate dielectric 110 may include traditional dielectric materials, such as doped or undoped silicon oxide, nitrogen, silicon, silicon nitride, silicon oxynitride, silicon carbide, metal silicide, metal oxide, a barrier layer, and/or other suitable materials and structures. In another example, the gate dielectric 110 may include high-k dielectric material, such as TaN, TiN, Ta₂O₅, HfO₂, ZrO₂, HfSiON, HfSiₓ, HfSiₓN_{y}, HfAlO₂, NiSiₓ, silicon nitride, aluminum oxide, tantalum pentoxide, zirconium oxide, barium strontium titanate, lead-lanthanum-zirconium-titanate, or other suitable materials. The gate dielectric 110 may have a thickness of less than about 50 angstroms. However, other thicknesses are contemplated for gate dielectric 110.

Formed over the gate dielectric 110 is a gate 112. The gate 112 may be a conductive material, such as doped or undoped polycrystalline silicon, aluminum, copper, cobalt, nickel, tungsten, combinations or alloys thereof, or other suitable materials. The gate 112 has a height h1. The height h1 of the gate 112 may be less than, equal to, or greater than a width of gate 112. In one embodiment, the gate 112 has a width of about 45 nm and a height of about 80 nm. In another embodiment, the gate 112 has a width of about 32 nm.

Proximate to the gate 112 is a gate spacer 114. The gate spacer 114 may be any suitable dielectric material, such as silicon dioxide, silicon carbide, silicon nitride, silicon carbon nitride, silicon oxynitride, silicon oxycarbide, or any combination thereof. In one embodiment, the gate spacer 114 is silicon nitride. The gate spacer 114 has an inner surface 116 proximate to the gate 112. The gate spacer 114 also has an outer surface 118, which may be curved, erect, angled, irregularly shaped, a combination thereof, or any other shape. The gate spacer 114 has a height h2 that is greater than the height h1 of the gate 112 such that an upper portion of the inner surface 116 is not proximate to the gate 112. The gate spacer 114 may be a single contiguous structure that partially or complete encircles the gate 112, or the gate spacer 114 may include two or more discrete structures formed proximate to the gate 112. In some embodiments an upper surface of the gate 112 approximately defines a plane that divides the gate spacer 114 into two portions such that neither portion is greater than about 90% of the entire gate spacer 114.

In some embodiments, the height hi of the gate 112 may be less than about 80 nm, and the height h2 of the gate spacer 114 may be greater than about 100 nm. For instance, in one embodiment, the height h1 is about 79 nm and the height h2 is about 107 nm.

In other embodiments, the height h2 of the gate spacer 114 is greater than about 110% of the height h1. In some embodiments, the height h2 is greater than about 150% of the height h1. And in some embodiments, the height h2 is between about 105% and about 300% of the height h1.

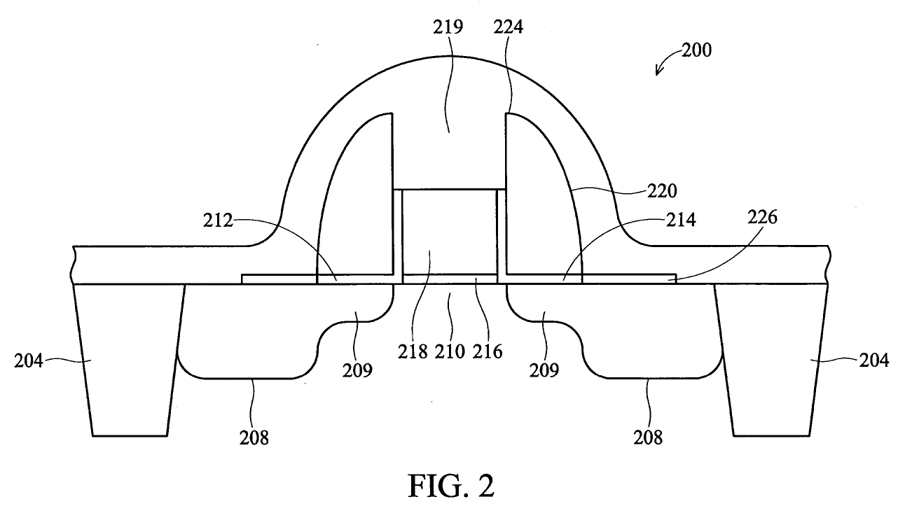

Referring now to FIG. 2, illustrated is a cross-sectional view of another embodiment of a semiconductor device 200. The device 200 includes a substrate 202 that may include silicon, germanium, silicon-on-insulator (SOI), silicon with defective crystalline, and/or diamond or other suitable materials. The substrate 202 may be n-type doped or p-type doped. The substrate 202 may include shallow trench isolation (STI) structures 204. The STI structures 204 may be any suitable dielectric material to electrically isolate the device 200 from other structures (not shown) formed in substrate 200. For instance, the STI structures 204 may be silicon dioxide, silicon carbide, silicon nitride, or any other suitable dielectric. In one embodiment, the STI structures 204 may be silicon dioxide, which may be thermally grown, chemically deposited, or formed using any other suitable technique. Furthermore, the semiconductor device 200 and STI structures 204 may employ the transistor mobility improvement of U.S. Pat. No. 7,190,036 to Ko, et al., which is hereby incorporated by reference.

The substrate 202 further includes source 206 and drain 208. The source 206 and the drain 208 may be n-type doped or p-type doped, and the doping may be achieved by any suitable technique, for example ion implantation. The source 206 and the drain 208 may be doped with phosphorus, boron, arsenic, BF₂, a combination thereof, or any other suitable dopant. In one embodiment, the source 206 and the drain 208 are doped similarly to each other and are doped differently than other regions of substrate 202. The source 206 may include a lightly doped (LDD) region 207 that is less heavily doped than other regions of the source 206. Similarly, the drain 208 may include a lightly doped (LDD) region 209 that is less heavily doped than other regions of the drain 208. Substrate 202 may also include a channel 210 between source 206 and drain 208. The lightly doped regions 207 and 209 may be near the channel 210. The channel 210 may be n-type doped or p-type doped, and in one embodiment it is doped the same as substrate 202.

Formed over the source 206 is a source electrode 212. The source electrode 212 includes a conductive material, for instance, a metal. In one embodiment, the source electrode 212 is copper. In another embodiment, the source electrode 212 is aluminum. In still another embodiment, the source electrode 212 is tungsten. However, it is contemplated that the source electrode 212 may be any suitable conductive material. A silicide layer (not shown) may be present between the source 206 and the source electrode 212.

Formed over the drain 208 is a drain electrode 214. The drain electrode 214 includes a conductive material, for instance, a metal. In one embodiment, the drain electrode 214 is copper. In another embodiment, the drain electrode 214 is aluminum. In still another embodiment, the drain electrode 214 is tungsten. However, it is contemplated that the drain electrode 214 may be any suitable conductive material. A silicide layer (not shown) may be present between the drain 208 and the drain electrode 214.

Formed over the substrate 202 is a gate dielectric 216. The gate dielectric 216 may be formed partially or entirely over the channel 210. The gate dielectric 216 includes any suitable dielectric material, including doped or undoped silicon dioxide, nitrogen, silicon, silicon nitride, silicon oxynitride, silicon carbide, metal silicide, metal oxide, a barrier layer, and/or other suitable materials and structures.

The device 200 may include a gate 218 formed over the gate dielectric 216. The gate 218 may be a conductive material, such as doped or undoped polycrystalline silicon, aluminum, copper, cobalt, nickel, tungsten, a combination or alloy thereof, or other suitable materials. The gate 218 may have a height and a width. The height of the gate 218 may be measured from the substrate 202 to an upper surface 219. Thus, the measurement of the height of the gate 218 may include the gate dielectric 216. The height of the gate 218 may be less than, equal to, or greater than the width of gate 218. In one embodiment, the gate 218 has a width of about 45 nm and a height of about 80 nm. In another embodiment, the gate 218 has a width of about 32 nm.

The device 200 may further include an insulating layer 220 formed over the substrate and proximate to the gate dielectric 216 and the gate 218. The insulating layer 220 may be any suitable material, such as a dielectric material. In one embodiment, the insulating layer 220 is silicon dioxide.

Formed over the insulating layer 220 is a gate spacer 222. The gate spacer 222 may be composed of any suitable material, such as a dielectric material. In one embodiment, the gate spacer 222 is silicon nitride. The gate spacer 222 may have an uppermost point 224 that is substantially higher than the upper surface 219 of gate 218. The gate spacer 222 may further have a height measured from the same reference as used in measuring the height of the gate 218. For example, the height of the gate spacer 222 may be measured from the substrate 202 to the uppermost point 224. The height of gate spacer 222 is greater than the height of the gate 218.

The gate spacer 222 may have a height and/or composition selected to induce a physical stress in the channel 210. The gate spacer 222 may affect a physical stress in the channel 210 along zero, one, two, or three axes, and the effects may or may not be the same along different axes. For example, the gate spacer 222 may induce a tensile stress in one direction and induce a compressive stress in another direction.

In one example, the semiconductor device 200 may be a PMOS transistor. The gate spacer 222 may have a height and/or composition that induces a compressive stress in the channel 210 along a line between the source 206 and the drain 208. Thus the gate spacer 222 may increase a compressive stress, or reduce a tensile stress, that would have otherwise been in the channel 210. The induced compressive stress may increase the mobility of holes and may improve performance of the PMOS transistor.

In another example, the semiconductor device 200 may be an NMOS transistor. The gate spacer 222 may have a height and/or composition that induces a tensile stress in the channel 210 along a line between the source 206 and the drain 208. Thus the gate spacer 222 may decrease a compressive stress, or increase a tensile stress, that would have otherwise been in the channel 210. The induced tensile stress may increase the mobility of electrons and may improve performance of the NMOS transistor.

In other embodiments, the gate spacer 222 may be formed of a material and/or may have a height that does not induce a stress in the channel 210.

The gate spacer 222 may have a height and/or composition that reduces the implantation of ions into the lightly doped areas 207 and 209 of the source 206 and the drain 208. For instance, lightly doped (LDD) areas 207 and 209 may be formed using a first ion implantation before the gate spacer 222 is formed. Then, after the gate spacer 222 is formed, a second, higher dose of ion implantation may be used to form the source 206 and the drain 208. The gate spacer 222 may reduce the penetration of ions from the second, higher-dose ion implantation into the lightly doped areas 207 and 209. Reducing the implantation of ions at lightly doped areas 207 and 209 may reduce or prevent device failures caused by short channel punch through.

Device 200 may further include a contact etch stop layer 226, which may be composed of silicon nitride, silicon dioxide, silicon oxynitride, or any other suitable dielectric or etch stop material. The contact etch stop layer 226 may be formed over some, all, or none of the STI structures 204, the source 206, the source electrode 212, the gate spacer 222, the gate 224, the drain 208, the drain electrode 214, and the substrate 202. The contact etch stop layer 226 may be conformal or it may be nonconformal. In some embodiments, the contact etch stop layer 226 may be a material that induces a physical stress in the channel 210. For example, the contact etch stop layer 226 may be a material that induces a tensile stress or a compressive stress in the channel 210. The contact etch stop layer 226 may affect a physical stress in the channel along zero, one, two, or three axes, and the effects may or may not be the same along different axes. For example, the contact etch stop layer 226 may induce a tensile stress along a horizontal line between the source 206 and the drain 208, and it may induce a compressive stress in a vertical direction. In other embodiments, the contact etch stop layer 226 may not affect a stress in the channel 210.

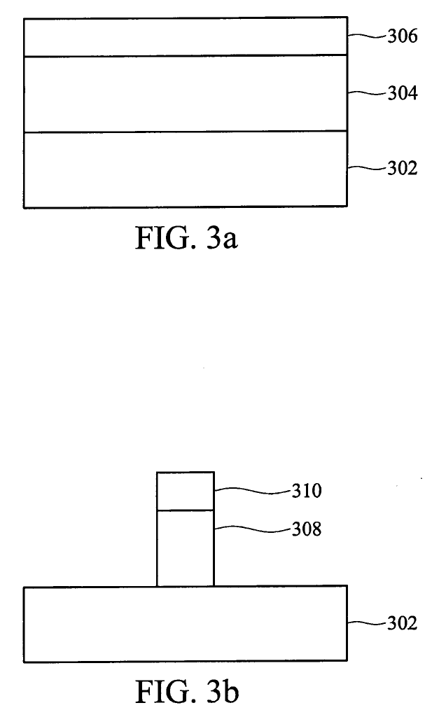

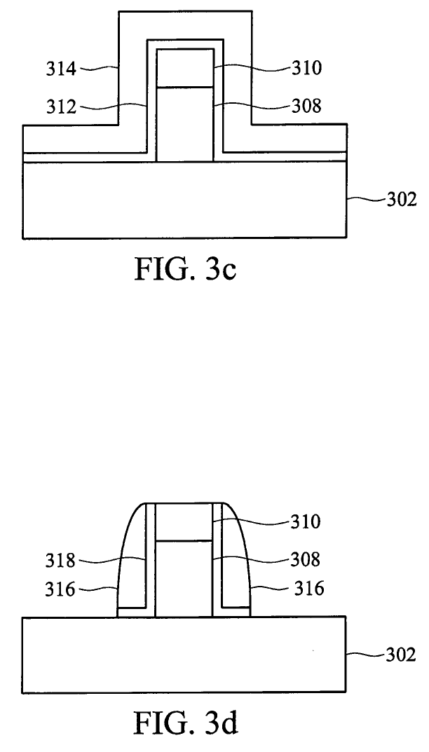

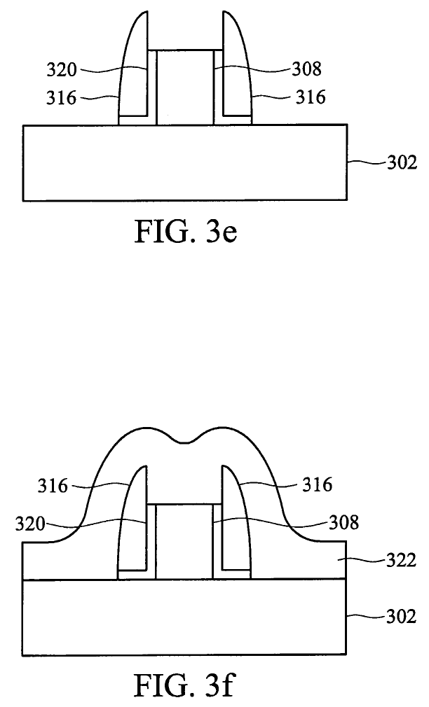

Referring now to FIGS. 3a-3f, illustrated are a series of cross-sectional views showing intermediate steps of an exemplary method of fabricating a semiconductor device. FIG. 3a shows a substrate 302, which includes any suitable semiconductor substrate material. For instance, the substrate 302 may include doped or undoped silicon, germanium, carbon, a combination thereof, or any other suitable semiconductor substrate material. The substrate 302 may be provided with one or more isolation features (not shown). The isolation features may include local oxidation of silicon (LOCOS) structures and/or shallow trench isolation (STI) structures that are formed in the substrate 302 to electrically isolate device areas. The substrate 302 may be provided with or without source and/or drain regions.

Formed over substrate 302 is a gate layer 304, which may be any suitable gate material, such as doped or undoped polycrystalline silicon, aluminum, copper, cobalt, nickel, tungsten, a combination or alloy thereof, or other suitable materials. The gate layer 304 may be formed by any suitable method, such as by physical vapor deposition (PVD), chemical vapor deposition (CVD), plasma enhanced chemical vapor deposition (PECVD), high density plasma chemical vapor deposition (HDPCVD), low pressure chemical vapor deposition (LPCVD), film deposition, or any other suitable deposition or film growth technique. The gate layer 304 may be separated from substrate 302 by a gate oxide layer (not shown). The gate layer 304 may have a thickness between about 50 angstroms and about 1000 angstroms. However, the present disclosure contemplates other thicknesses of the gate layer 304. In one embodiment, the gate layer 304 may have a thickness of about 500 angstroms.

Formed over the gate layer 304 is a hard mask layer 306. The hard mask layer 306 may include any suitable hard mask material, for instance silicon dioxide, silicon carbide, silicon nitride, or silicon oxynitride. The hard mask layer 306 may be a material that does not degrade, melt, or decompose at temperatures reached in subsequent processing steps. For instance, the hard mask layer 306 may be a material that is stable at temperatures up to about 700 degrees Celsius. The hard mask layer 306 may be formed using PVD, CVD, PECVD, HDPCVD, LPCVD, film deposition, thermal growth, or any suitable technique. In one embodiment, the hard mask layer 306 is silicon dioxide deposited by the reaction of silane with oxygen. In another embodiment, the hard mask layer 306 is silicon dioxide deposited by the reaction of tetraethylorthosilicate (TEOS) with ozone.

FIG. 3b shows that the gate layer 304 and hard mask layer 306 of FIG. 3a have been etched to form a gate 308 and a hard mask 310. The etching may have been accomplished by using a patterned photoresist mask (not shown). The etching may have been a dry plasma etch, wet etch, or other suitable process for removing material from the gate layer 304 and hard mask layer 306.

FIG. 3c shows that an insulating layer 312 has been formed over the substrate 302, gate 308, and hard mask 310. The insulating layer 312 may be silicon dioxide or any other suitable insulating material and may be very thin. In one embodiment, the insulating layer 312 is about 40 angstroms. However, thicker and thinner insulating layers are also contemplated. The insulating layer 312 may be deposited using PVD, CVD, PECVD, HDPCVD, LPCVD, film deposition, thermal growth, or any other suitable technique. In some embodiments, it is contemplated that there may not be an insulating layer 312. In some other embodiments, the insulating layer 312 may be of a material selected to promote the adhesion or deposition of subsequent layers. One subsequent layer may be a spacer layer 314, which may be formed over the insulating layer 312. The spacer layer 314 may be silicon dioxide, silicon nitride, silicon carbide, silicon oxynitride, or any other suitable material for forming gate spacers. The spacer layer 314 may be a different material than the hard mask 310. In some embodiments, the spacer layer 314 is conformally deposited over the insulating layer 312. The spacer layer 314 may be deposited using PVD, CVD, PECVD, HDPCVD, LPCVD, film deposition, thermal growth, or any other suitable technique.

FIG. 3d shows that the spacer layer 314 has been etched to form a gate spacer 316. The insulating layer 312 has also been etched to form an insulator 318. In some embodiments, the etching is an anisotropic plasma etch.

FIG. 3e shows that the hard mask 310 and portions of the insulator 312 have been removed. A portion of the insulator 312 that was not removed is residual insulator 320. Removing the hard mask 310 may leave the gate spacer 316 taller than the gate 308. Any suitable technique capable of removing the hard mask 310 may be employed. For instance, the hard mask 310 may be removed using a photoresist etch back process so that structures (not shown) in the substrate 302 are not damaged.

FIG. 3f shows that a contact etch stop layer 322 has been formed over the substrate 302, gate 308, and gate spacer 316. The contact etch stop layer 322 may be silicon nitride, silicon dioxide, silicon oxynitride, a combination thereof, or any other suitable contact etch stop layer material. The contact etch stop layer 322 may be formed using any suitable method, such as by PVD, CVD, PECVD, HDPCVD, LPCVD, film deposition, or any other suitable deposition or film growth technique. The contact etch stop layer 322 may be conformal or it may be nonconformal. In some embodiments, the contact etch stop layer 322 may be a material that induces a physical stress in the substrate 302. For example, the contact etch stop layer 322 may be a material that induces a tensile stress or a compressive stress in the substrate 302. In other embodiments, the contact etch stop layer 322 may not induce a stress in the substrate 302.

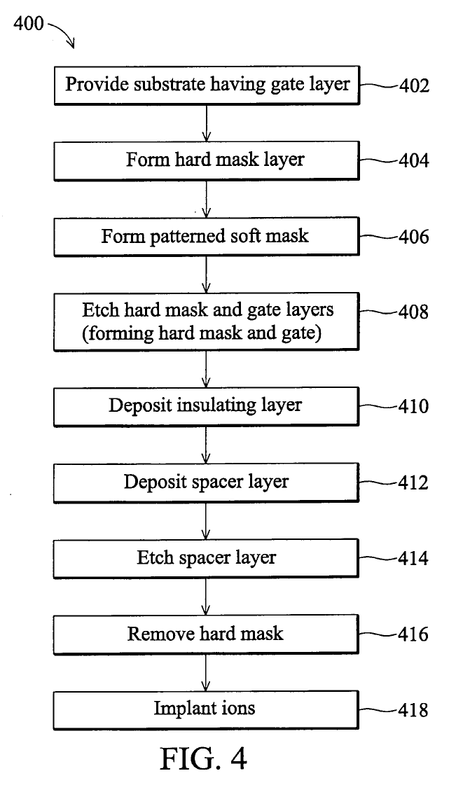

FIG. 4 illustrates an exemplary method 400 for forming a semiconductor device. The method 400 begins in step 402 with providing a substrate that has a gate layer. The substrate may include any suitable semiconductor substrate material, such as silicon, germanium, silicon-on-insulator (SOI), silicon with defective crystalline, and/or diamond or other suitable materials. The substrate may be doped or undoped, and the substrate may have isolation features such as LOCOS or STI structures to electrically isolate device areas.

The provided substrate may have a gate layer. The gate layer may be a conductive material, such as doped or undoped polycrystalline silicon, aluminum, copper, cobalt, nickel, tungsten, a combination or alloy thereof, or other suitable materials. The provided substrate may have a gate dielectric layer between the substrate and the gate layer.

The method 400 continues in step 404 with forming a hard mask layer over the gate layer. The hard mask layer may be silicon dioxide, or it may be another suitable material for forming a hard mask. A layer of silicon dioxide may be formed using PVD, CVD, PECVD, HDPCVD, LPCVD, film deposition, thermal growth, or any other suitable technique. In one embodiment, the hard mask layer is silicon dioxide deposited by the reaction of silane with oxygen. In another embodiment, the hard mask layer is silicon dioxide deposited by the reaction of tetraethylorthosilicate (TEOS) with ozone. The hard mask layer may have a thickness of about 500 angstroms, although other thicknesses are also contemplated.

In step 406, a patterned soft mask is formed over the hard mask layer. The patterned soft mask may be formed using a conventional technique, such as photolithography. The photolithography may include spin-coating a photoresist over the hard mask layer and exposing portions of the photoresist to an electromagnetic energy source through a reticle. The electromagnetic energy source may be an ultra-violet (UV), deep ultra-violet (DUV), X-ray, or other radiation source. For instance, the electromagnetic energy source may be a mercury lamp having a wavelength of 365 nm (I-line); a Krypton Fluoride (KrF) excimer laser with wavelength of 248 nm; or an Argon Fluoride (ArF) excimer laser with a wavelength of 193 nm. Additionally, immersion technology may be employed to lower the effective wavelength of the radiation.

The method 400 continues in step 408 with etching the hard mask layer and the gate layer to form a hard mask and a gate. The etching may be an anisotropic plasma etch capable of removing material from the hard mask layer and the gate layer without substantially removing the patterned soft mask formed in step 406. The etching of step 408 may produce a hard mask from the hard mask layer, and the hard mask may have a pattern that is substantially the same as the pattern of the patterned soft mask formed in step 406. After the etching, the patterned soft mask may be removed, leaving behind the hard mask and the gate.

Next in step 410, an insulating layer is deposited over the substrate, gate, and hard mask. The insulating layer may be silicon dioxide or any other suitable insulating material, and it may be very thin. In some embodiments, the insulating layer is conformally deposited. The insulating layer may be deposited using PVD, CVD, PECVD, HDPCVD, LPCVD, film deposition, thermal growth, or any other suitable technique.

The method 400 continues in step 412 with depositing a spacer layer. The spacer layer may be silicon dioxide, silicon nitride, silicon carbide, silicon oxynitride, or any other suitable material for forming gate spacers. The spacer layer may be a different material than the hard mask. In some embodiments, the spacer layer is conformally deposited over the insulating layer. The spacer layer may be deposited using PVD, CVD, PECVD, HDPCVD, LPCVD, film deposition, thermal growth, or any other suitable technique.

In step 414 the spacer layer is etched to form a gate spacer. The etching may be an anisotropic etch that removes material from horizontal surfaces more rapidly than from vertical surfaces.

The method 400 continues in step 416 with removing the hard mask. The hard mask may be removed using a technique that does not substantially affect the gate spacer or the substrate. For instance, a photoresist etch back process may be employed. With photoresist etch back, a photoresist or other sacrificial material is deposited to fill in low-lying areas, for example, the areas adjacent to the gate spacer. An etching process is then employed to remove the hard mask. Some of the photoresist or other sacrificial material may also be removed by the etching. The etching process may have an etch rate of the hard mask that is about equal to the etch rate of the photoresist or other sacrificial material, and the etch rate of the hard mask may be greater than the etch rate for the gate spacer. After the hard mask is etched away, the remaining photoresist or other sacrificial material may be removed using another technique, such as a HF acid wash.

Next in step 418, ions are implanted in the substrate to form source and drain regions. After step 418, the method 400 ends. However, it is contemplated that other steps may follow to continue the fabrication, testing and/or packaging of the semiconductor device.

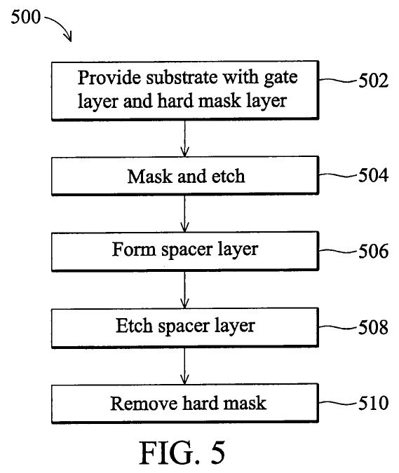

FIG. 5 illustrates another method 500 for forming a semiconductor device. The method 500 begins with step 502 providing a substrate with a gate layer and a hard mask layer. The substrate may include any suitable semiconductor substrate material, such as silicon, germanium, silicon-on-insulator (SOI), silicon with defective crystalline, and/or diamond or other suitable materials. The substrate may be doped or undoped, and the substrate may have isolation features such as LOCOS or STI structures to electrically isolate device areas.

The provided substrate may have a gate layer. The gate layer may be a conductive material, such as doped or undoped polycrystalline silicon, aluminum, copper, cobalt, nickel, tungsten, a combination or alloy thereof, or other suitable materials. The provided substrate may have a gate dielectric layer between the substrate and the gate layer.

The provided substrate may also have a hard mask layer over the gate layer. The hard mask layer may be silicon dioxide, or it may be another suitable material for forming a hard mask. A layer of silicon dioxide may have been formed using PVD, CVD, PECVD, HDPCVD, LPCVD, film deposition, thermal growth, or any suitable technique. In one embodiment, the hard mask layer is silicon dioxide deposited by the reaction of silane with oxygen. In another embodiment, the hard mask layer is silicon dioxide deposited by the reaction of tetraethylorthosilicate (TEOS) with ozone. The hard mask layer may have a thickness of about 500 angstroms, although other thicknesses are also contemplated.

In step 504, the gate layer and hard mask layer are etched using a patterned mask. The patterned mask may be a photoresist layer formed over the hard mask layer. The photoresist layer may have been deposited, exposed, and developed. The etching may be an anisotropic etch. The etching process may form a gate from the gate layer and a hard mask from the hard mask layer.

The method 500 continues in step 506 with forming a spacer layer. The spacer layer may be silicon dioxide, silicon nitride, silicon carbide, silicon oxynitride, or any other suitable material for forming gate spacers. The spacer layer may be a different material than the hard mask. In some embodiments, the spacer layer is conformally deposited over the insulating layer. The spacer layer may be deposited using PVD, CVD, PECVD, HDPCVD, LPCVD, film deposition, thermal growth, or any other suitable technique.

In step 508 the spacer layer is etched to form a gate spacer. The etching may be an anisotropic etch that removes material from horizontal surfaces more rapidly than from vertical surfaces.

The method 500 continues in step 510 with removing the hard mask. The hard mask may be removed using a technique that does not substantially affect the gate spacer or the substrate. For instance, a photoresist etch back process may be employed. After step 510, the method 500 ends. However, it is contemplated that other steps may follow to continue the fabrication, testing and/or packaging of the semiconductor device.

The present disclosure has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

What is claimed is:

1. A semiconductor device comprising:
a substrate;
a gate formed over the substrate and having a height; and
a gate spacer proximate to the gate and having a height;
wherein the height of the gate spacer is greater than the height of the gate.

2. A semiconductor device comprising:
a substrate;
a gate having a lower surface proximate to the substrate and an upper surface approximately parallel to the lower surface, the upper surface being located a first height from the lower surface of the gate as measured along a line perpendicular to the lower surface; and
a gate spacer having an approximately planar lower surface and an inner surface, the lower surface being proximate to the substrate, at least part of the inner surface being proximate to the gate and having a second height measured from the lower surface of the gate spacer along a line perpendicular to the lower surface of the gate spacer to a furthest point of the gate spacer;
wherein the second height is greater than the first height.

3. The device of claim 2 wherein the first height is less than about 80 nm and the second height is greater than about 100 nm.

4. The device of claim 2 wherein the second height is greater than or equal to 110% of the first height.

5. The device of claim 2 wherein the second height is greater than or equal to 150% of the first height.

6. The device of claim 2 wherein the second height is between about 105% and about 300% of the first height.

7. A semiconductor device comprising:
a semiconductive substrate comprising:
a channel,
a source adjacent to the channel, and
a drain adjacent to the channel and opposite the source;
a gate dielectric formed over the substrate and proximate to the channel;
a gate formed over the gate dielectric and having an upper surface; and
a gate spacer proximate to the gate;
wherein less than 90% of the gate spacer exists on either side of a plane approximately defined by the upper surface of the gate.

8. The device of claim 7 wherein the gate spacer is configured to induce a compressive stress in the channel.

9. The device of claim 7 wherein the gate spacer is configured to induce a tensile stress in the channel.

10. The device of claim 7 further comprising:
a contact etch stop layer formed over the gate and the gate spacer and configured to induce a stress in the channel.

11. A method comprising:
providing a substrate;
forming a gate layer over the substrate;
forming a hard mask layer over the gate layer;
forming a patterned soft mask over the hard mask layer;
etching the hard mask layer and the gate layer to form a patterned hard mask and a gate;
removing the patterned soft mask;
forming a spacer layer;
etching the spacer layer to form a gate spacer proximate to the gate and patterned hard mask; and
removing the patterned hard mask.

12. The method of claim 11 wherein removing the patterned hard mask comprises using a photoresist etch back process.

13. The method of claim 11 wherein the hard mask layer comprises silicon dioxide.

14. The method of claim 11 further comprising:
implanting ions in the substrate to form source and drain regions.

15. The method of claim 11 wherein the hard mask layer is formed to have a thickness between about 50 and 1000 angstroms.

16. The method of claim 11 wherein the gate spacer is formed such that it has a height that is between about 105% and 300% of a height of the gate.

17. The method of claim 11 further comprising:
depositing a contact etch stop layer over the gate and the gate spacer.

18. The method of claim 17 wherein the contact etch stop layer is operative to induce a stress in a channel, wherein the stress is a tensile stress if the semiconductor device is an NMOS device and the stress is a compressive stress if the semiconductor device is a PMOS device.

19. The method of claim 11 further comprising:
before forming the gate spacer, performing a first ion implantation to form lightly doped source and drain regions in the substrate; and
after forming the gate spacer, performing a second ion implantation to form heavily doped source and drain regions in the substrate;
wherein the gate spacer has a height operative to substantially prevent the penetration of ions from the second ion implantation into the lightly doped source and drain regions.
